(19) United States
(12) Patent Application Publication
(10) Pub. No.: US 2007/0057631 A1
(43) Pub. Date: Mar. 15, 2007

(54) ORGANIC EL PANEL

(75) Inventor: Hiroki TSUJIMURA, Ukyo-ku, Kyoto (JP)

Correspondence Address: ROHM CO., LTD.;C/O KEATING & BENNETT, LLP, 8180 GREENSBORO DRIVE, SUITE 850, MCLEAN, VA, 22102, US

(73) Assignee: ROHM CO., LTD., Ukyo-ku (JP)

(21) Appl. No.: 11/468,854

(22) Filed: Aug. 31, 2006

(30) Foreign Application Priority Data
Sep. 14, 2005 (JP) 2005-267151

(51) Int. Cl. H01L 51/00

(52) U.S. Cl. 313/506

(57) ABSTRACT

An organic EL panel includes an organic layer including a light emission layer, the organic layer including a plurality of segments arrayed in a striped pattern; first and second electrodes arranged on opposite sides of the organic layer, the first electrode being made of metal and disposed on a side opposite to a light emission side of the organic EL panel; and an insulating film arranged between the segments of the organic layer, the insulating film including a metal film arranged to reflect light from the organic layer toward the metal electrode.

### BACKGROUND OF THE INVENTION

1. Field of the Invention

The present invention relates to an organic EL panel with an enhanced light emission rate.

2. Description of the Related Art

A conventional organic electroluminescence (EL) device having a bottom emission system is constructed in such a manner that light generated in an organic layer is emitted from the side of a positive electrode. An organic EL panel, which is an example of a display or a like device using a device having the bottom emission system, utilizes a passive matrix system, as shown in FIG. 6, for instance.

FIG. 5 is a diagram showing a cross-sectional view taken along the line A-A in FIG. 6. Referring to FIG. 5, a layer of positive electrodes 22 is arranged in a striped pattern on a glass substrate 21. An organic layer 23 including a light emission layer is arranged in a striped pattern on the positive electrodes 22 along the positive electrodes 22. A layer of negative electrodes 25 is arranged in a striped pattern to intersect with the positive electrodes 22.

The organic layer 23 is provided between the positive electrode 22 and the negative electrode 25. Applying a voltage between the negative electrode 25 and the positive electrode 22 having a matrix arrangement in a time-series manner causes a selected portion of the organic layer 23 at an intersection of the negative electrode 25 and the positive electrode 22 to emit light at a certain point in time, thereby driving the organic EL panel.

An insulating film 24 is disposed to prevent a portion of the organic layer 23 other than the portion of the organic layer 23 at the intersection of the negative electrode 25 and the positive electrode 22 from emitting light, i.e., to prevent crosstalk. A transparent electrode, such as an ITO (indium-tin oxide) electrode, is used as the positive electrode 22 to allow the light generated in the organic layer 23 to be emitted from the panel. The light generated in the organic layer 23 is emitted from a front surface of the glass panel 21 through the positive electrode 22 and the glass substrate 21.

The light emission rate in a conventional organic EL panel is at most about 20% relative to the total amount of light generated in the organic layer 23, while the rest of the light, i.e., about 80% is diffused, as will be discussed below. Consequently, it is impossible to effectively utilize the organic EL panel, causing a great loss in its efficiency.

The light generated in the organic layer 23 is irradiated in all directions, that is, over 360 degrees. The irradiated light includes a light component, as shown by the arrow “b” in FIG. 5, which travels along the panel by transverse propagation therethrough, and a light component, as shown by the arrow “a” in FIG. 5, which is directed downward from the organic layer 23, but travels in a zigzag manner while being reflected inside the glass substrate 21 by total reflection, because an incident angle defined by the glass substrate 21 and a boundary surface of the glass substrate with the air is greater than a critical angle. These diffused light components cannot be emitted from the organic EL panel. The loss of the diffused light component “a” is about 35%, and the loss of the diffused light component “b” is about 45%.

In view of this, Japanese Unexamined Patent Publication No. 2003-100464 proposes providing a reflection rib in order to emit the diffused light component “b”, which is transversely diffused through the organic layer 23 and which causes great loss of light, from the front side of the glass substrate 21 so as to enhance the light emission rate. The arrangement disclosed in this publication, however, requires trapezoidal reflective members, as dedicated structural elements, which are provided between the adjacent segments of the organic layer. In addition to the difficulty of aligning the reflective members, this arrangement complicates the manufacturing process thus raising production costs.

### SUMMARY OF THE INVENTION

In order to overcome the problems described above, preferred embodiments of the present invention provide an organic EL panel with an enhanced light emission rate in a simplified arrangement without the need of a complex alignment, and without providing a dedicated structural member.

According to a first preferred embodiment of the present invention, an organic EL panel includes an organic layer having a light emission layer, the organic layer including a plurality of segments arrayed in a striped pattern; first and second electrodes arranged on both sides of the organic layer, respectively, the first electrode disposed on a side opposite to a light emission side of the organic EL panel and being a metal electrode; and an insulating film arranged between the segments of the organic layer, the insulating film including a metal film for reflecting light from the organic layer toward the metal electrode.

According to another preferred embodiment of the present invention, the metal film is arranged on an inner side relative to the metal electrode, that is, below the metal electrode.

According to another preferred embodiment of the present invention, the metal film is arranged on an inner side relative to the second electrode disposed on the light emission side of the organic EL panel, that is, above the second electrode.

According to another preferred embodiment of the present invention, the metal film is arranged in a substantially inverted U-shape.

According to the present preferred embodiment, the first electrode of the electrodes disposed on the both sides of the organic layer, which is disposed on the side opposite to the light emission side of the organic EL panel, is a metal electrode so as to effectively emit light from the segments of the organic layer arrayed in the striped pattern, and the metal film is arranged in the insulating film which is provided between the segments of the organic layer. This arrangement allows the light diffused transversely between the segments to be reflected from the metal film, and then, allows this reflected light to be reflected from the metal electrode. This guides the light in the intended emission direction, thereby enhancing the light emission rate.

Other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a diagram showing a cross-sectional structure of an organic EL panel according to a preferred embodiment of the present invention.

FIG. 2 is an enlarged cross sectional view showing portion “A” in FIG. 1.

FIG. 3 is a diagram showing an arrangement of a portion of an organic EL device.

FIGS. 4A through 4G are diagrams showing a process of producing the organic EL panel according to a preferred embodiment of the present invention.

FIG. 5 is a diagram showing a cross-sectional structure of a conventional organic EL panel.

FIG. 6 is a diagram showing an overview of the conventional organic EL panel shown in FIG. 5.

### DETAILED DESCRIPTION OF PREFERRED EMBODIMENTS

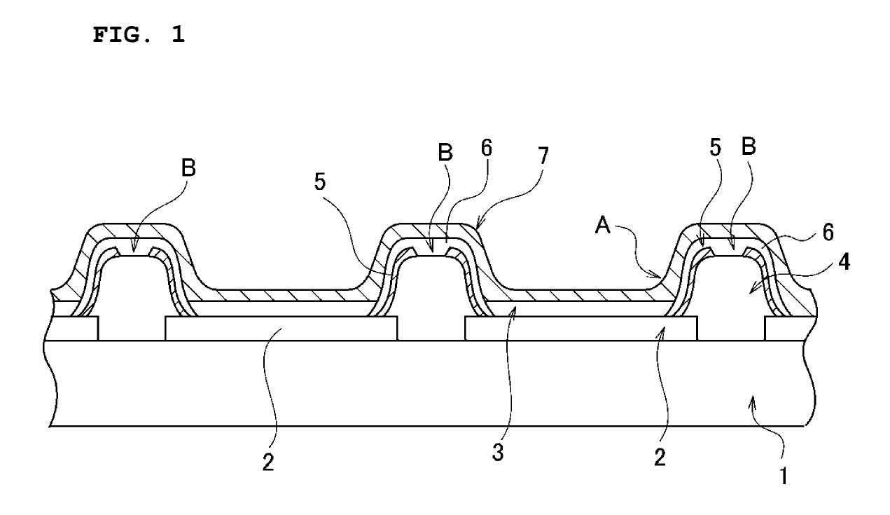

In the following, preferred embodiments of the present invention are described in reference to the drawings. FIG. 1 is a diagram showing a cross-sectional structure of an organic EL panel according to a first preferred embodiment of the present invention.

Referring to FIG. 1, a positive electrode 2 is arranged in a striped pattern, in other words, is provided with segments in rows parallel to each other on a transparent glass substrate 1 that transmits light. An organic layer 3 including a light emission layer is arranged in a striped pattern, in other words, is provided with segments on the positive electrode 2 in the same direction as the arrayed direction of the segments of the positive electrode 2. Ametal negative electrode 7 is arranged in a striped pattern, in other words, is provided with segments in a row such that a segment of each negative electrode 7 intersects with a segment of each positive electrode 2. The negative electrode 7 is arranged such that the adjacent segments of the organic layer 3 are connected to each other through the negative electrode 7.

The segments of the positive electrode 2 serve as scanning lines, and the segments of the negative electrode 7 serve as data lines. The segments of the positive electrode 2, i.e., the scanning lines, and the segments of the negative electrode 7, i.e., the data lines, define a matrix. The organic layer 3 is disposed between the positive electrode 2 and the negative electrode 7 at positions where the positive electrode 2 and the negative electrode 7 intersect with each other. Applying a voltage between the positive electrode 2 and the negative electrode 7 in a time-series manner causes a selected portion of the organic layer 3 at one of the intersections of the positive electrode 2 and the negative electrode 7 to emit light at a certain point in time. An insulating film 4 and an insulating film 6 are arranged to prevent a portion of the organic layer 3 other than the selected portion from emitting light. A transparent electrode such as an ITO (indium tin oxide) electrode or an IZO (indium zinc oxide) electrode is used as the positive electrode 2 so as to allow light to be emitted from the organic EL panel. Ametal such as aluminum (Al) is used as a material for the negative electrode 7.

A metal film 5 made of a metal material such as aluminum (Al), chromium (Cr), or molybdenum (Mo) is provided between the insulating film 4 and the insulating film 6, which are arranged to prevent crosstalk, as mentioned above. As shown in FIG. 1, the metal film 5 is provided at an inner side of the positive electrode 2, i.e., at an upward position relative to the positive electrode 2, and at an inner side of the negative electrode 7, i.e., at a downward position relative to the negative electrode 7. The metal film 5 is arranged in a substantially inverted U-shape.

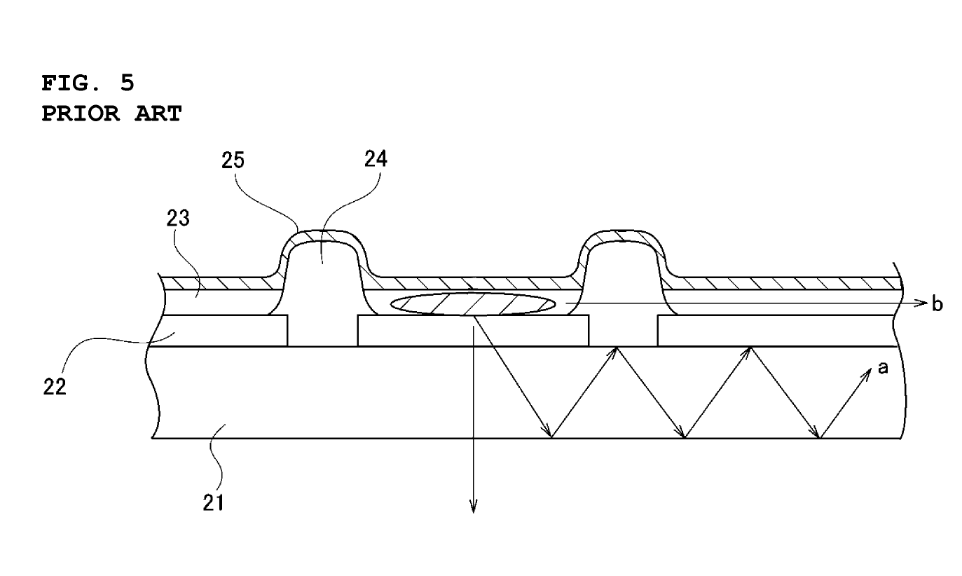

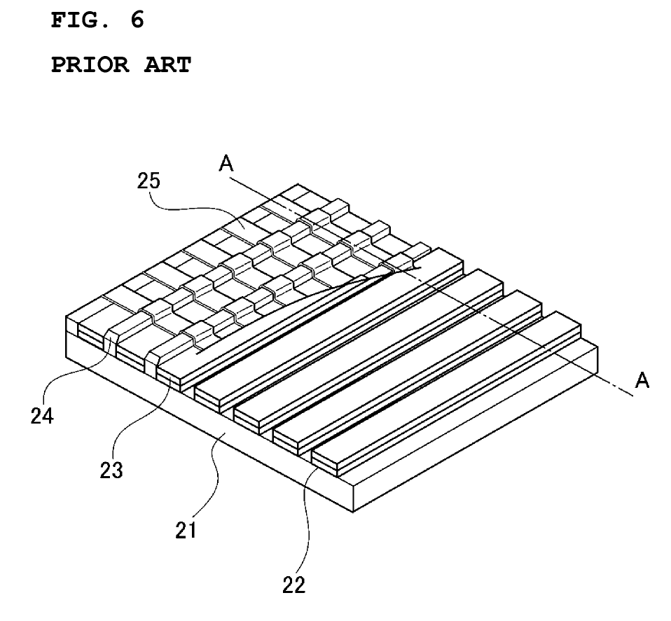

As compared with the conventional organic EL panel shown in FIG. 5, the organic EL panel in FIG. 1 has a construction in which the metal film 5 is sandwiched between the insulating films. Also, the metal film 5 is not provided at a position corresponding to a peak portion “B” of the substantially inverted U-shaped insulating film 4. In other words, the metal film 5 is discontinued and divided into two portions with respect to the portion “B”. This arrangement prevents the adjacent segments of the positive electrode 2 from short-circuiting.

Each segment of the positive electrode 2, the organic layer 3, and the negative electrode 7, which are provided on the glass substrate 1, define an organic EL device corresponding to one pixel. As shown in FIG. 3, the organic EL device is substantially similar to an organic EL device having an organic layer 3 including an organic positive hole carrier layer 31, an organic luminescent layer 32, and an organic electron carrier layer 33 arranged on a glass substrate 1 as a base member, and a positive electrode 2 and a negative electrode 7 arranged on both sides of the organic layer 3, respectively. With this construction, the organic luminescent layer 32 emits light when a certain voltage is applied between the positive electrode 2 and the negative electrode 7. Alternatively, the organic layer 3 may be composed of layers other than the organic positive hole carrier layer and the organic electron carrier layer, e.g., an organic positive hole injection layer and an organic electron injection layer.

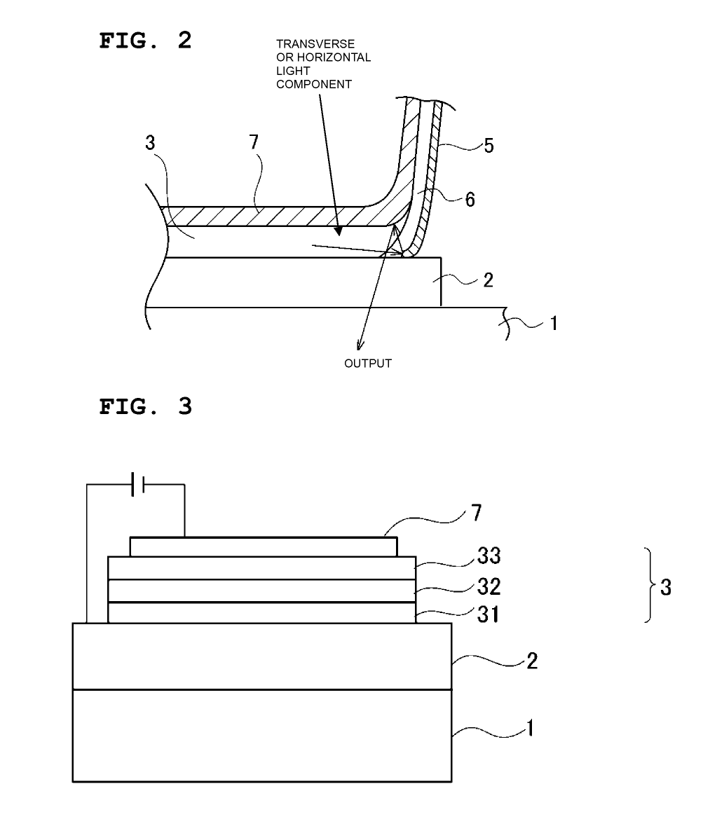

FIG. 2 is an enlarged view of a portion “A” in FIG. 1, showing an operation of the organic EL panel having the above arrangement. Light emitted from the organic layer 3 includes a light component which is guided in a direction of the segments of the organic layer 3 adjacent to each other, i.e., in a transverse direction or a horizontal direction, as shown by the arrowed line in FIG. 2, in addition to a light component directed toward the glass substrate 1. Since skirt portions of the substantially inverted U-shaped metal film 5 are shaped into curved portions, the transversely or horizontally guided light component is directed toward the negative electrode 7 by specular reflection from the curved portions of the metal film 5.

Since the negative electrode 7 is a metal electrode whose segment has a width wider than the width of the segment of the organic layer 3, the reflected light toward the negative electrode 7 causes specular reflection from the negative electrode 7, and the reflected light is directed toward the glass substrate 1, as shown in FIG. 2. In the case where an incident angle defined by the glass substrate 1 and a boundary surface of the glass substrate 1 with the air is smaller than a critical angle, the reflected light is emitted from a lower portion of the glass substrate 1.

As mentioned above, the diffused light directed transversely through the organic layer 3 is emitted outside the organic EL panel by the two reflections, i.e., the reflection from the metal film 5 and the reflection from the negative electrode 7. This enhances the light emission rate, and obtains a sufficient luminance with less electric power. Also, the arrangement enables the organic EL device to be driven by a low electric power, which makes it possible to extend the useful life of the organic EL device. The metal film 5 may be preferably made of a metal having a high reflectance to a wavelength of a light component which is to be emitted outside the organic EL device.

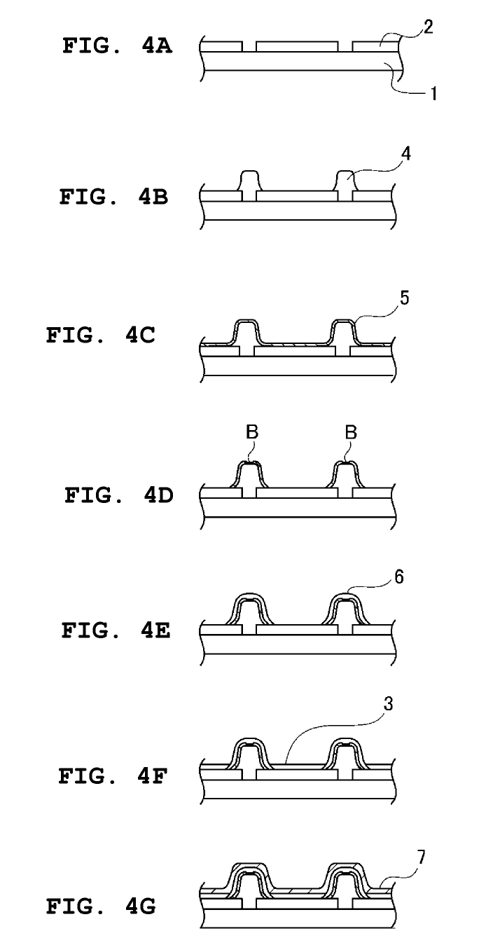

FIGS. 4A through 4G are diagrams showing a process of producing the organic EL device in FIG. 1. Well-known methods such as photolithography, etching, and vapor deposition are some examples of methods for producing the organic EL device. As shown in FIG. 4A, the segments of the positive electrode 2 as a transparent electrode are arranged on the glass substrate 1 in a striped pattern according to a patterning process. Then, as shown in FIG. 4B, the segments of the insulating film 4 as a first insulating film are each formed between the adjacent segments of the positive electrode 2. As a result, as shown in FIG. 4B, each segment of the insulating film 4 is laminated or formed into a substantially inverted U-shape, with skirt portions thereof having curved portions.

Subsequently, as shown in FIG. 4C, the metal film 5 with a film thickness of several hundred A, for example, is provided on the insulating film 4. Then, as shown in FIG. 4D, each segment of the metal film 5 is divided into two portions by removing a top portion “B” of the segment by, for example, etching so as to prevent the adjacent segments of the positive electrode 2 from short-circuiting. After removing a photoresist by washing, the insulating film 6 as a second insulating film is provided on the metal film 5, as shown in FIG. 4E. In this way, each segment of the metal film 5 and each segment of the insulating film 6 are laminated into a substantially inverted U-shape, with skirt portions thereof having curved portions.

Then, as shown in FIG. 4F, the segments of the organic layer 3 extending in the same direction as the positive electrode 2 are provided on the positive electrode 2. Finally, as shown in FIG. 4G, the organic EL panel shown in FIG. 1 is produced by forming the negative electrode 7 in a direction intersecting with or substantially perpendicular to the positive electrode 2.

The organic EL panel may be produced as mentioned above. As compared with the conventional organic EL panel shown in FIG. 5, the organic EL panel of the present preferred embodiment may be produced by simply adding a step of providing the metal film 5 between the insulating films, as shown in FIG. 4C through FIG. 4E. This eliminates the need for providing a dedicated structural member, and enables producing the organic EL panel in a simplified manner and with less cost.

Also, since the skirt portions of the substantially inverted U-shaped segments of the metal film 5 are smoothly shaped into the curved portions, this arrangement eliminates the need of a dedicated alignment, and enables light transversely diffused through the organic layer 3 to be efficiently reflected toward the negative electrode 7.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. An organic EL panel comprising:
an organic layer including a light emission layer and a plurality of segments arrayed in a striped pattern;
first and second electrodes arranged on opposite sides of the organic layer, the first electrode made of metal and disposed on a side opposite to a light emission side of the organic EL panel; and
an insulating film arranged between the segments of the organic layer, the insulating film including a metal film arranged to reflect light from the organic layer toward the metal electrode.

2. The organic EL panel according to claim 1, wherein the metal film is arranged on an inner side relative to the metal electrode, and below the metal electrode of the organic EL panel.

3. The organic EL panel according to claim 2, wherein the metal film is arranged on an inner side relative to the second electrode disposed on the light emission side of the organic EL panel, and above the second electrode of the organic EL panel.

4. The organic EL panel according to claim 1, wherein the metal film is arranged in a substantially inverted U-shape.

5. The organic EL panel according to claim 1, wherein the insulating film includes first and second insulating films, the metal film arranged between the first and second insulating films.

6. The organic EL panel according to claim 5, wherein the first insulating film is arranged in a substantially inverted U-shape, the metal film is discontinuous such that a peak portion of the substantially inverted U-shaped first insulating film is not covered by the metal film.

7. The organic EL panel according to claim 5, wherein the metal film includes a curved portion arranged to reflect the light from the organic layer toward the metal electrode.

8. A method for producing an organic EL panel comprising:
providing a striped pattern of first electrodes on a glass substrate;
providing segments of an insulating film between the first electrodes, the insulating film including first and second insulating films with a metal film arranged between the first and second insulating films;
forming an organic layer including a light emission layer over the first electrodes; and
forming a striped pattern of second electrodes over the organic layer and the first electrodes.

9. The method for producing an organic EL panel according to claim 8, wherein the first insulating film and the metal film are arranged in a substantially inverted U-shape.

10. The method for producing an organic EL panel according to claim 9, further comprising the step of removing a portion of the metal film at a peak portion of the substantially inverted U-shaped first insulating film.
